(19) United States
(12) Patent Application Publication
(10) Pub. No.: US 2026/0344072 A1
(43) Pub. Date: Oct. 29, 2026

(54) High-Performance Nanocrystal Photodetector Design

(71) Applicants: Thomas Mlynarski, Washington, DC (US); Sushant Sonde, Westmont, IL (US); Ryan Sellers, Chicago, IL (US); Yong Chang, Naperville, IL (US); Silviu Velicu, Willowbrook, IL (US)

(72) Inventors: Thomas Mlynarski, Washington, DC (US); Sushant Sonde, Westmont, IL (US); Ryan Sellers, Chicago, IL (US); Yong Chang, Naperville, IL (US); Silviu Velicu, Willowbrook, IL (US)

(21) Appl. No.: 19/558,495

(22) Filed: Mar. 6, 2026

Related U.S. Application Data
(60) Provisional application No. 63/768,051, filed on Mar. 6, 2025.

(51) Int. Cl. H10F 39/00; H10F 39/12

(52) U.S. Cl. CPC H10F 39/8027; H10F 39/1935

(57) ABSTRACT

A nanocrystal photodetector is described herein that includes: an anode, a multi-point contact carrier collection center, a semiconductor nanocrystal surrounding the anode, and the multi-point contact carrier collection center, and a cathode surrounding the nanocrystal with a readout circuit located beneath the anode, the multi-point contact carrier collection center, the cathode and the nanocrystal. The multi-point contact carrier collection center comprises a central region surrounding the anode and in electrical contact therewith, and legs or spokes extending in a radial direction outward of the central region.

### BACKGROUND

FIG. 1 presents a cross-sectional view of an individual pixel in a conventional photoconductive device incorporating semiconductor nanocrystals, such as PbS, PbSe, or HgTe etc. The device includes a silicon readout chip or read out integrated circuit (ROIC).

Deposited on, or adhered onto, the ROIC 1, are a semiconductor nanocrystal 2, an anode 3, and a cathode 4. Conventionally, the anode 3 is a central electrode in a rectangular pixel, surrounded by the nanocrystal 2 and the cathode 4 surrounds the nanocrystal 2.

Such conventional pixels are described on US Patent 2011/0226934, FIGS. 3A and 3C and corresponding text, herein incorporated by reference.

The present inventors have recognized that surface trap density and carrier mobility are key factors that limit the performance of semiconductor nanocrystal-based photoconductive (PC) devices.

### SUMMARY

A nanocrystal photodetector is described herein that includes: an anode, a multi-point contact carrier collection center, a semiconductor nanocrystal surrounding the anode, and the multi-point contact carrier collection center, and a cathode surrounding the nanocrystal with a readout circuit located beneath the anode, the multi-point contact carrier collection center, the cathode and the nanocrystal. The multi-point contact carrier collection center comprises a central region surrounding the anode and in electrical contact therewith, and legs or spokes extending in a radial direction outward of the central region.

The multi-point contact carrier collection center can comprise a cylindrical head formed on a distal end of each leg. The cylindrical head can be oriented to have a central axis normal to an exposed surface of the nanocrystal. For example, the multi-point contact carrier collection center can include eight legs.

As a further enhancement, a higher carrier mobility layer can be provided between the readout circuit and the nanocrystal.

The exemplary embodiments of the present invention enhance carrier collection efficiency by narrowing the channel of the active device, positioning carrier collection closer to the carrier generation centers, and implementing a higher mobility transport layer for the generated carriers.

Numerous other advantages and features of the present invention will become readily apparent from the following detailed description of the invention and the embodiments thereof, and from the accompanying drawings.

### BRIEF DESCRIPTION OF THE DRAWINGS

FIG. 1 is a cross-sectional view of an individual pixel design in a conventional semiconductor nanocrystal-based photoconductive device.

FIG. 2 is a schematical cross-sectional view of an individual pixel design in a semiconductor nanocrystal-based photoconductive device, modified with a multi-point contact carrier collection center.

FIG. 3A is a fragmentary perspective view of a focal plane array of photoconductive devices featuring one variant of multi-point contact carrier collection centers with the semiconductor nanocrystal removed to see underlying portions.

FIG. 3B is an enlarged, fragmentary perspective view of a portion of the focal plane array of FIG. 3A with the semiconductor nanocrystal removed to see underlying portions.

FIG. 3C is an enlarged, fragmentary perspective view of a portion of the focal plane array of FIG. 3A with the semiconductor nanocrystal deposited.

FIG. 4 is a schematical cross-sectional view of an individual pixel design in a semiconductor nanocrystal-based photoconductive device, modified with a multi-point contact carrier collection centers and higher carrier mobility transport layer.

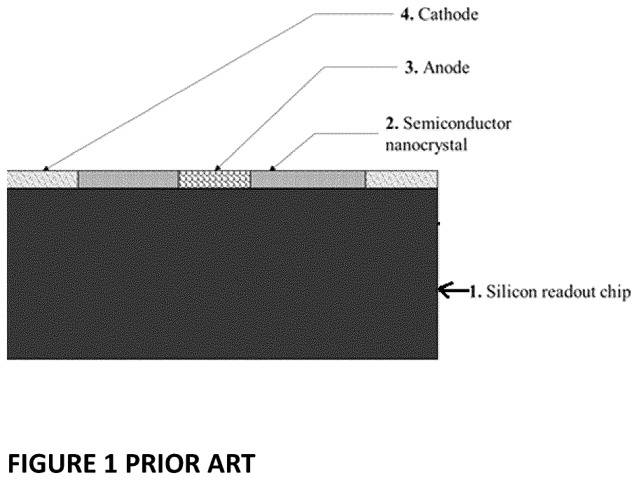

### DETAILED DESCRIPTION

While this invention is susceptible of embodiment in many different forms, there are shown in the drawings, and will be described herein in detail, specific embodiments thereof with the understanding that the present disclosure is to be considered as an exemplification of the principles of the invention and is not intended to limit the invention to the specific embodiments illustrated.

This application claims the benefit of U.S. Prov. Ser. No. 63/768,051, filed Mar. 6, 2025, herein incorporated by reference in its entirety.

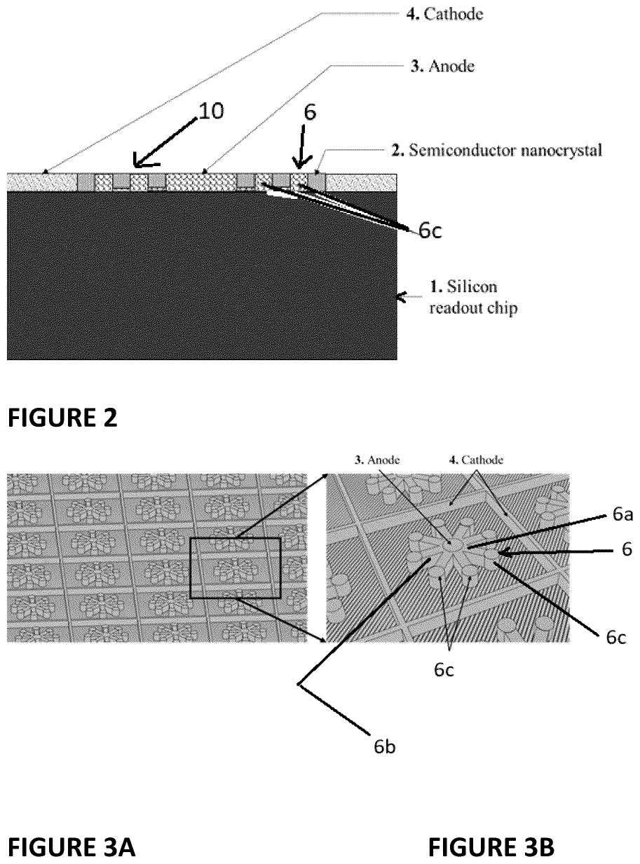

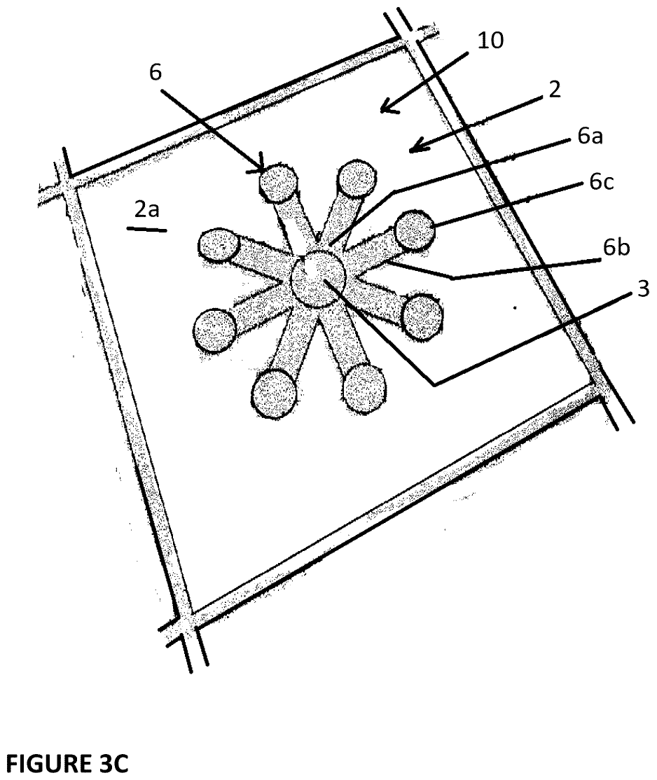

FIGS. 2-3C show an individual pixel 10 which includes an anode 3 surrounded by a multi-point contact carrier collection center 6. The center 6 can take on various shapes, one of which is depicted in isometric view in FIGS. 3A and 3B.

In designs similar to the embodiment shown in FIGS. 2-3C, the multi-point contact carrier collection center 6 is metallic. The collection center 6 has a hub portion 6a which closely surrounds the anode 3 and is in electrical contact therewith. Spokes or legs 6b are formed with, and extend radially outward from, the hub 6a. Each leg 6b is terminated with a cylindrical head 6c having a central axis normal to a top surface 1a of the nanocrystal ROIC 1. The collection center 6 shown in FIGS. 3A-3C has eight spokes or legs 6b.

The collection center 6 in FIGS. 3A and 3B is shown before the nanocrystal 2 is deposited onto the ROIC 1. FIG. 3C shows the pixel after the nanocrystal layer 2 is deposited. The nanocrystal layer 2 surrounds the collection center 6 and fills the pixel out to the cathode 4. Only top surfaces of the anode 3 and collection center 6 are visible.

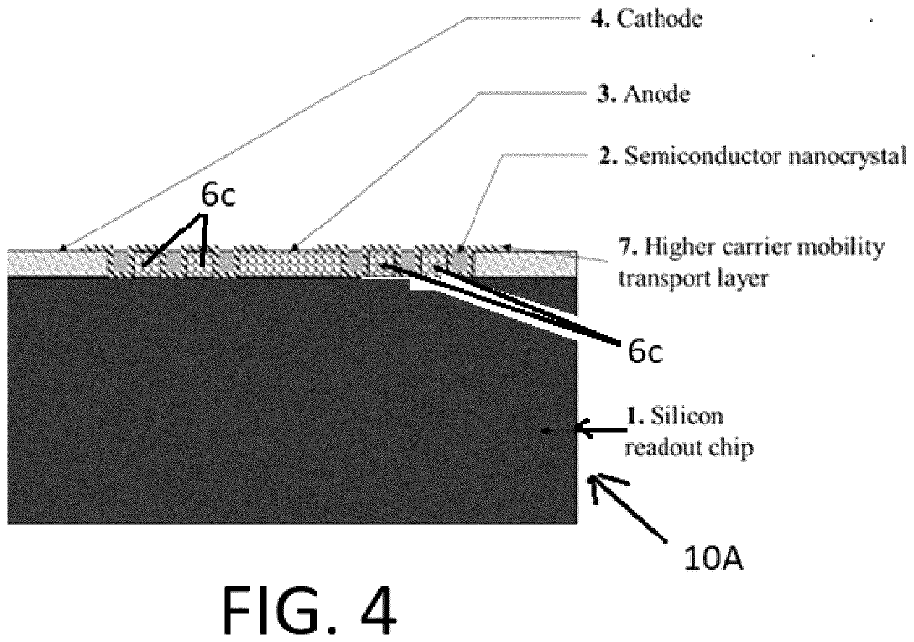

FIG. 4 shows a cross-sectional view of an alternate embodiment pixel 10A. The pixel 10A is identical to the pixel 10 except as noted. The pixel 10A is also represented by FIGS. 3A-3C. The pixel 10A includes a high carrier mobility transport layer 7. The layer 7 is deposited onto the anode 3 and the collection center 6, before the semiconductor nanocrystal 2 is deposited onto the layer 7. As shown in FIG. 4, the layer 7 is present on the top surface of, and the side surfaces of, the anode 3 and collection center 6, including the cylindrical heads 6c.

The sectional views 2 and 4 do not show the legs 6b in order to show underlying parts and for clarity of description.

The multi-point contact carrier collection center 6 can take on various shapes, one of which is depicted in FIGS. 3A and 3B. In designs similar to FIG. 4, the multi-point contact carrier collection center can either be metallic or non-metallic. The higher mobility transport layer 7 can be made of materials such as molybdenum disulfide (MoS2).

The embodiments shown in FIGS. 2-3C and FIG. 4 can be applied to both single element detectors and imaging detector array configurations.

From the foregoing, it will be observed that numerous variations and modifications may be effectuated without departing from the spirit and scope of the invention. It is to be understood that no limitation with respect to the specific apparatus illustrated herein is intended or should be inferred.

The invention claimed is:

1. A nanocrystal photodetector, comprising:
an anode;
a multi-point collection center surrounding the anode and in electrical contact therewith;
a semiconductor nanocrystal surrounding the multi-point collection center;
a cathode surrounding the nanocrystal;
wherein the multi-point collection center includes heads spaced from the anode and substantially surrounded by the semiconductor nanocrystal;
a readout circuit located beneath the anode, cathode and nanocrystal.

2. The nanocrystal photodetector according to claim 1, wherein the multi-point collection center comprises a central hub and legs extending in a radial direction outward of the central region; and each leg formed with one of the heads.

3. The nanocrystal photodetector according to claim 2, wherein the heads are cylindrical, the heads oriented to have a central axis normal to an outer surface of the nanocrystal.

4. The nanocrystal photodetector according to claim 3, wherein the multi-point collection center comprises eight legs.

5. The nanocrystal photodetector according to claim 1, further comprising a higher carrier mobility layer arranged between the readout circuit and the nanocrystal, and arranged over the multi-point collection center.

6. The nanocrystal photodetector according to claim 5, wherein the higher carrier mobility layer is composed of molybdenum disulfide (MoS2).

7. The nanocrystal photodetector according to claim 1, wherein the multi-point collection center comprises a central hub and legs extending in a radial direction outward of the central region; and each leg formed with one of the heads, and further comprising a higher carrier mobility layer arranged between the readout circuit and the nanocrystal, and arranged over the multi-point collection center.

8. The nanocrystal photodetector according to claim 7, further comprising a higher carrier mobility layer arranged between the readout circuit and the nanocrystal, and arranged over the multi-point collection center.

9. The nanocrystal photodetector according to claim 8, wherein the higher carrier mobility layer is composed of molybdenum disulfide (MoS2).

10. The nanocrystal photodetector according to claim 1, wherein the multi-point collection center comprises a central hub and legs extending in a radial direction outward of the central region; and each leg formed with one of the heads; and the heads are cylindrical, the heads oriented to have a central axis normal to an outer surface of the nanocrystal; and the multi-point collection center comprises eight legs; and further comprising a higher carrier mobility layer arranged between the readout circuit and the nanocrystal, and arranged over the multi-point collection center.

11. The nanocrystal photodetector according to claim 10, further comprising a higher carrier mobility layer arranged between the readout circuit and the nanocrystal, and arranged over the multi-point collection center.

12. The nanocrystal photodetector according to claim 11, wherein the higher carrier mobility layer is composed of molybdenum disulfide (MoS2).

13. The nanocrystal photodetector according to claim 1, wherein the heads are cylindrical, the heads oriented to have a central axis normal to an outer surface of the nanocrystal.

14. The nanocrystal photodetector according to claim 13, wherein the multi-point collection center comprises eight heads.

15. The nanocrystal photodetector according to claim 14, further comprising a higher carrier mobility layer arranged between the readout circuit and the nanocrystal, and arranged over the multi-point collection center.

16. The nanocrystal photodetector according to claim 15, wherein the higher carrier mobility layer is composed of molybdenum disulfide (MoS2).
